(19) United States
(12) Patent Application Publication
(10) Pub. No.: US 2024/0172568 A1
(43) Pub. Date: May 23, 2024

(54) RECONFIGURABLE WIDEBAND CRYOGENIC RADIO FREQUENCY POWER DEPENDENT POWER LIMITER

(71) Applicants: Navjot Kaur KHAIRA, Kanata (CA); Tejinder SINGH, Kanata (CA); Raafat Rezk MANSOUR, Waterloo (CA)

(72) Inventors: Navjot Kaur KHAIRA, Kanata (CA); Tejinder SINGH, Kanata (CA); Raafat Rezk MANSOUR, Waterloo (CA)

(21) Appl. No.: 18/115,098

(22) Filed: Feb. 28, 2023

Related U.S. Application Data
(60) Provisional application No. 63/315,440, filed on Mar. 1, 2022.

(51) Int. Cl. H10N 60/355; H01P 1/18; H10N 69/00

(52) U.S. Cl. CPC H10N 60/355; H01P 1/184; H10N 69/00

(57) ABSTRACT

A monolithic radio frequency (RF) power limiter for protecting sensitive superconductor receiver components from high-power microwave signals is disclosed. In some embodiments, two low-Tc superconductor (LTS) microstrip lines; one of which is coupled with an array of RF superconducting quantum interference devices (rf-SQUIDs); are combined with a pair of hybrid couplers to provide the power limiting operation at very low RF power levels. A microstrip line coupled to an array of rf-SQUIDs behaves as a power dependent phase shifter and its phase can be controlled by the input RF power. In one embodiment, a monolithically integrated wideband hybrid coupler is used as it dictates the bandwidth of the overall device.

### CROSS-REFERENCE TO RELATED APPLICATIONS

This application claims the benefit of and priority under 35 U.S.C. § 119(e) to U.S. Provisional Patent Application Ser. No. 63/315,440 entitled “Monolithic Low Temperature Superconductor rf-SQUIDs Based Wideband Power Dependent Power Limiter,” filed Mar. 1, 2022, which is incorporated herein by reference in its entirety for all purposes.

### FIELD OF THE INVENTION

The present invention is related to microwave circuits and more particularly to the realization of monolithically integrated low temperature superconductor-based power limiter for application in cryogenic radio frequency (RF) communication devices, broadly systems.

### BACKGROUND OF THE INVENTION

Cryogenic radiofrequency (RF) receivers utilize low-temperature superconductor (LTS) Josephson Junction (JJ) based analog-to-digital converter (ADC) to digitize the RF signal directly from the antenna without the need of an analog down-conversion circuit. Such ADCs available in the prior art are based on rapid single-flux-quantum (RSFQ) technology, hence, they are at a high risk of getting damaged even by RF signals with very low power levels above −15 dBm. In addition to the ADCs, analog circuits like low-noise amplifiers (LNAs) in the prior art also require high-performance input signal limiters. Most power limiters are not capable of limiting such low power levels. An LTS power limiter having the provision to provide protection against power levels above −15 dBm and can be monolithically integrated with other components on the superconducting chip is disclosed in the present invention.

The most common configurations of a limiter circuit available in the prior art utilize semiconductor PIN diodes or Schottky diodes connected in single-stage, multi-stage, anti-parallel, or stacked fashion. Such semiconductor diode-based limiters have a major limitation that the threshold power level is high and cannot be reduced below a certain power level. Various RF-MEMS based power limiters have also been reported utilizing the self-actuation phenomenon of the MEMS switches at high RF power levels or varactors to control the input signal. The advantages of using MEMS for power limiter applications include linearity, low power consumption, high isolation, and low insertion loss. However, reliability issues of the MEMS devices and the high threshold RF power level for limiting are the major drawbacks of this approach. Another approach used to develop microwave power limiting devices is based on reversible semiconductor-to-metal transition of vanadium dioxide thin films, but they fail to offer low threshold power levels. The magnetostatic wave (MSW) frequency selective limiters have significantly low threshold power levels (<−25 dBm), but MSW are long wavelength spin waves that exist only over a limited frequency range (400 MHz to 4 GHz).

The previous attempts to develop a superconducting power limiter utilize the switching of high temperature superconductor (HTS) transmission line from low-loss superconducting state to the high-loss normal state when the microwave currents in the device exceed the critical value at high RF power levels. A major drawback of such designs is that all of the energy is dissipated into the superconductor at its switching to the normal state, causing excessive heating of the superconductor and delayed recovery of the super-conducting state after the operation. Moreover, all the above techniques are not amenable to monolithic integration with superconducting receivers.

### SUMMARY OF THE INVENTION

Various embodiments are directed to a monolithic radio frequency (RF) power limiter including: two low-Tc superconductor (LTS) microstrip lines, one of which is coupled with an array of RF superconducting quantum interference devices (rf-SQUIDs), are combined with a pair of hybrid couplers to provide the power limiting operation at very low RF power levels. With the recently growing interest in quantum computers, this invention on power limiter can also serve as a valuable addition to the quantum engineering library by limiting the RF power of the control signals provided to the sensitive qubits and has tremendous applications for protecting sensitive superconductor receiver components from high-power microwave signals in quantum measurement systems.

In various other embodiments, the key concept is built on the fact that a microstrip line coupled to an array of rf-SQUIDs behaves as a power dependent phase shifter and its phase can be controlled by the input RF power.

In still various other embodiments, the behavior of a RF power-controlled power dependent phase shifter phenomenon is exploited to achieve the desired RF power limiting operation.

In still various other embodiments, the device is fabricated using an eight-layer niobium-based superconducting process node SFQ5ee by MIT Lincoln Laboratory.

In still various other embodiments, a monolithically integrated wideband hybrid coupler is used in this design as it dictates the bandwidth of the overall device.

In still various other embodiments, the operating frequency of power limiter is 10 GHz with 2 GHz bandwidth.

In still various other embodiments, the performance of the device is measured for input RF power levels ranging from −30 dBm to +10 dBm, as well as arising intermodulation products are experimentally investigated.

In still various other embodiments, the output power increases linearly with the input power up to −15 dBm.

In still various other embodiments, for higher power levels, the device offers an increasing attenuation to limit the output RF power starting above −15 dBm.

In still various other embodiments, radio frequency superconducting quantum interference devices (rf-SQUIDs) as the active elements are used for achieving the power limiting operation.

In still various other embodiments, the disclosed power limiter demonstrates a threshold limiting power of −15 dBm and can be monolithically integrated with other superconducting components.

### BRIEF DESCRIPTION OF THE DRAWINGS

Embodiments herein will hereinafter be described in conjunction with the appended drawings provided to illustrate and not to limit the scope of the claims, wherein like designations denote like elements.

FIG. 1 is a block diagram of the power limiter of the present invention.

FIG. 2 is a circuit diagram, front view and 3D view of the phase tuning circuit utilized in the present invention.

FIG. 3 is a circuit diagram, front view and 3D view of the fixed phase circuit utilized in the present invention.

FIG. 4 is a circuit model of a unit cell with transmission line section and rf-SQUID utilized in the present invention.

FIG. 5 illustrates the 3D view drawing of the fixed and tunable phase circuit implementation utilized in the present invention.

FIG. 6 illustrates the optical micrograph of the disclosed power limiter highlighting the two quadrature coupler sections with two meandered microstrip transmission lines.

FIG. 7 illustrates the simulated and measured RF performance of the standalone hybrid coupler over 8-18 GHz.

FIG. 8 illustrates the experimental data of the tunable phase shift circuit utilized in the present invention.

FIG. 9 illustrates the experimentally measured insertion loss and the return loss response of the disclosed power limiter.

FIG. 10 illustrates experimentally measured insertion loss, return loss, and output RF power of the power limiter circuit.

FIG. 11 illustrates two tone intermodulation response of the power limiter at different input RF power levels ranging from −30 dBm to +5 dBm.

### DETAILED DESCRIPTION OF PREFERRED EMBODIMENTS

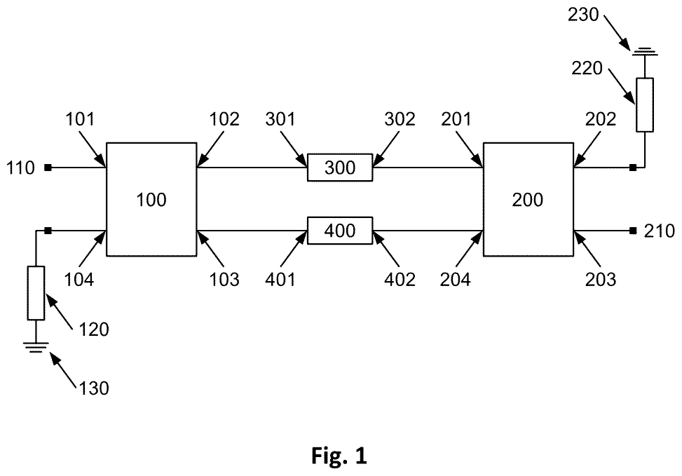

Referring to FIG. 1, a block diagram of the power dependent power limiter of the present invention shows two quadrature hybrid couplers, namely input hybrid coupler 100 and output hybrid coupler 200, a fixed phase transmission line 300 and a tunable phase transmission line circuit 400. The power limiter device has an RF input port 110 and an RF output port 210.

Hybrid couplers 100 and 200 have four ports. Coupler 100 has an input port 101, thru port 102, coupled port 103, and isolated port 104. Similarly, hybrid coupler 200 has an input port 201, thru port 202, coupled port 203, and isolated port 204. Couplers 100 and 200 are designed using co-planar waveguide (CPW) based tandem coupled line architecture. This topology allows the monolithic integration with other superconducting devices on the same chip.

The isolated port 104 of the input hybrid coupler 100 is terminated with matched load 120. The ground connection 130 is highlighted in the FIG. 1 to show the matched load. The port 202 of the output coupler 200 is terminated with matched load 220. The ground connection 230 is highlighted in the FIG. 1 to show the matched load. Matched load 120 and 220 are exactly the same, but 120 is connected with 100 while 220 is connected with 200. The fixed phase transmission line 300 has one input port 301 and one output port 302. The variable or tunable phase circuit 400 has one input port 401 and one output port 402.

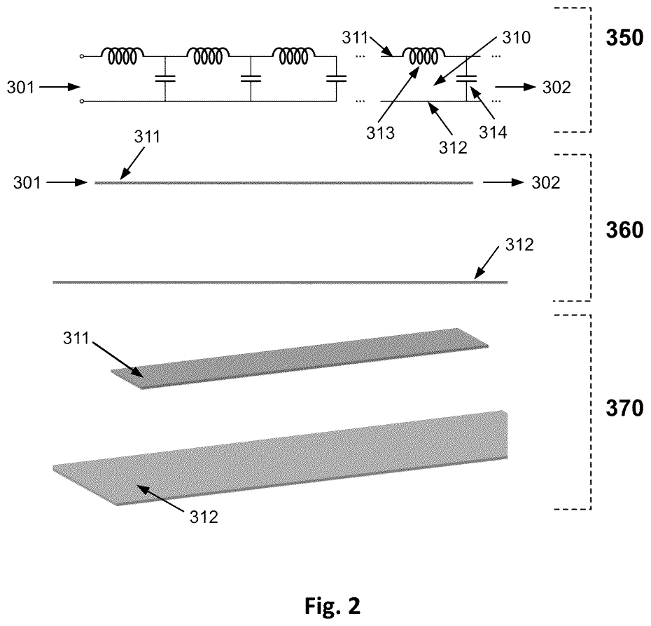

Referring FIG. 2, an equivalent circuit representation 350 of a superconducting microstrip transmission line (TL) 310 having a top conductor 311 and a bottom or ground conductor 312. The TL 310 is represented using distributed elements such as inductance 313 and capacitance 314. The RF signal on 310 travels between at input port 301 and an output port 302. The cross-sectional view 360 illustrates a top conductor 311 and the ground conductor 312. The 3D illustration 370 highlights the top conductor 311 and the bottom conductor 312.

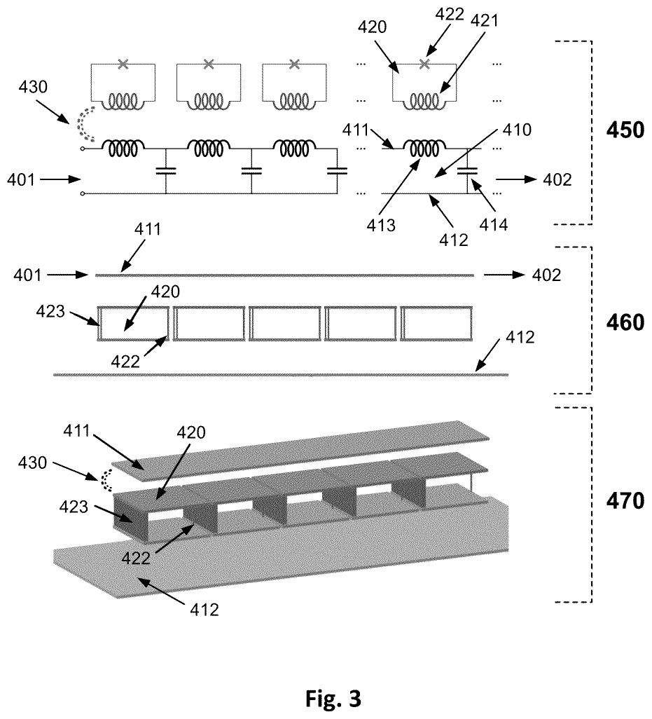

Referring FIG. 3, an equivalent circuit representation 450 of a superconducting microstrip transmission line (TL) 410 having a top conductor 411 and a bottom or ground conductor 412 coupled to an array of radio-frequency superconducting quantum interference devices (rf-SQUIDs) 420 having a Josephson Junction (JJ) 422 and the inductance of the SQUID loop 421. The TL 410 is represented using distributed elements such as inductance 413 and capacitance 414. The RF signal on 410 travels between at input port 401 and an output port 402. The 410 and 420 are coupled having a mutual coupling 430 between two TLs. The cross-sectional view 460 illustrates a top conductor 411, the ground conductor 412, rf-SQUID unit cell 420 having a Josephson Junction 422 and interconnects 423. The 3D illustration 470 highlights the top conductor 411, the bottom conductor 412, mutual coupling parameter 430, unit cell 420, JJ 422, and interconnects 423.

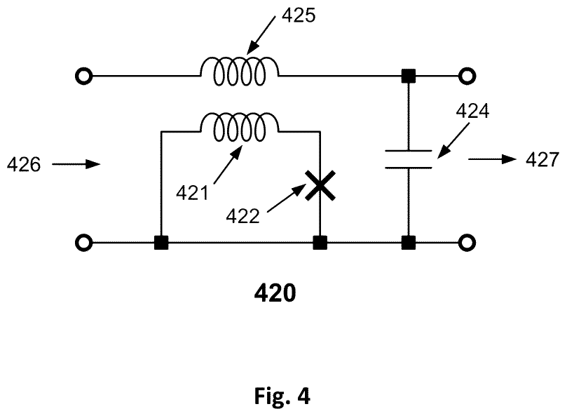

Referring FIG. 4, a circuit model of a unit cell 420 with TL section 425 having inductance Lₘ 413, SQUID inductance L_{sq} 421, a JJ 422 with inductance Lⱼ, and capacitance Cₘ 424. The signal travels between ports 426 and 427.

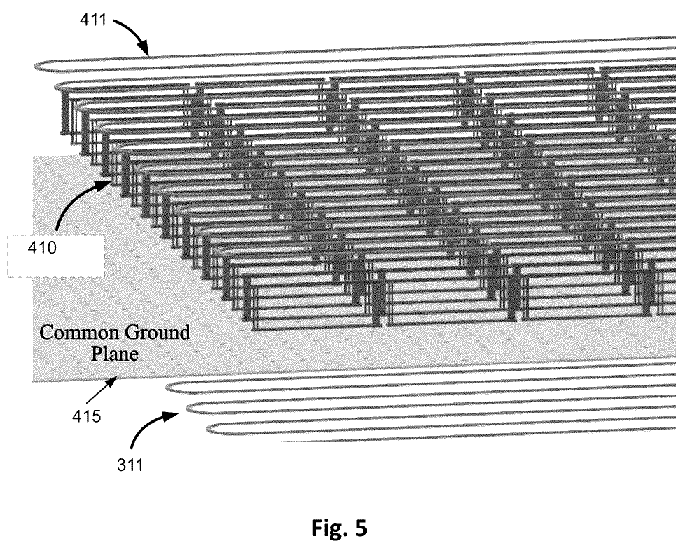

Referring FIG. 5, the layout of the combined 300 and 400 sections is illustrated having a superconducting meandered microstrip TLs 411 acting as a top conductor of the 400, a distributed array of rf-SQUIDs 410 and a fixed microstrip TL 311 acting as a top conductor of the 300-section used in the power limiter. The top microstrip 411 is coupled to rf-SQUIDs 410 placed below it. The top microstrip 411 and the bottom microstrip line 311 shares a common ground plane 415.

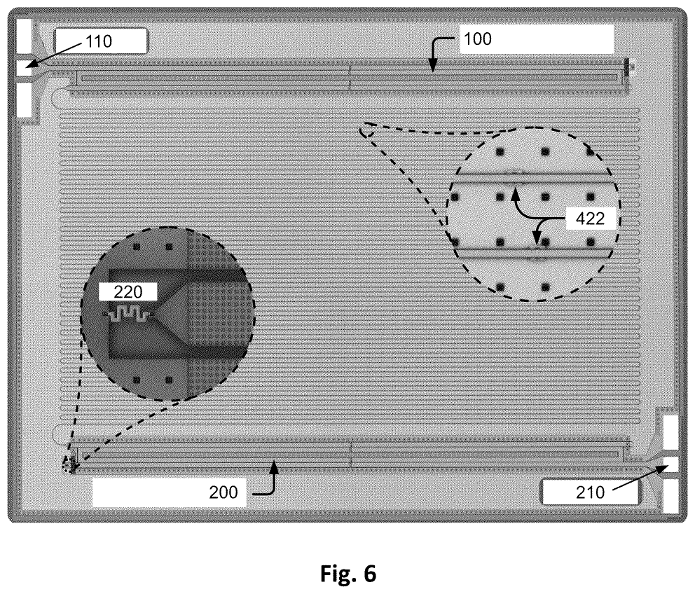

Referring FIG. 6, the optical micrograph of the disclosed power limiter is illustrated highlighting the monolithic integration of two hybrid couplers 100 and 200 with two meandered TLs. The JJs 422 underneath the top microstrip TL and the matched load termination 220 are highlighted. Input signal is given at port 110 and output is measured at port 210 of the power limiter.

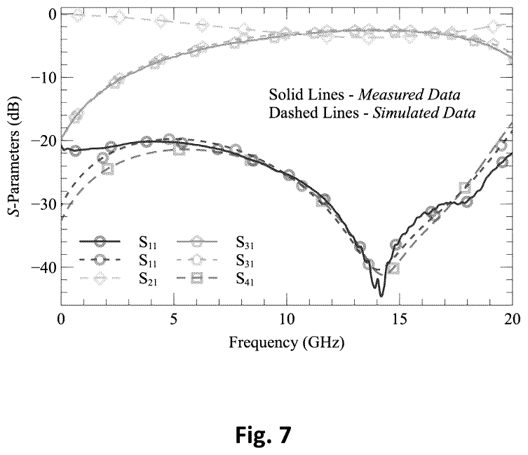

The couplers 100 and 200 have two center conductors placed side by side and the bridges connecting the individual ground places and the signal lines are routed from a niobium layer using interconnects, which provides significant improvement in performance compared to if air bridges/wire bonds were used as it is the case with prior art. The couplers 100 and 200 are simulated using electromagnetic modeling tool to get the desired wideband RF performance. The simulated performance of the optimized hybrid coupler is illustrated in FIG. 7. In order to experimentally measure the standalone devices, a separate coupler is designed in which two of its ports are terminated with matched loads 120 and the S-parameters are measured between the two remaining ports. Experimental and simulated data up to 20 GHz is illustrated in FIG. 7. A coupling of 3 dB was obtained in the target frequency range of 8 GHz to 18 GHz with the measured insertion loss at the coupled port<1 dB and the return loss>22 dB.

A superconducting TL 410 coupled to an array of rf-SQUIDs 420 placed throughout its length between the top conductor 411 and the ground plane 412. Each 420 used in the design is a Nb-based superconducting loop extending on two niobium layers shunted by the connecting niobium-filled interconnects 423 on one end and a Nb-AlOx-Nb tunnel JJ 422 on the other end. The amount of RF power provided to the microstrip TL controls the flux through 420. Individual rf-SQUID 420 acts as a flux sensitive variable inductor, and since it is magnetically coupled 430 to the 410, change in SQUID inductance 421 causes change in the effective inductance of the TL 413 and hence the phase of the output signal.

In order to investigate the amount of phase shift provided by a 410 coupled to 420, the structure shown in FIG. 3 comprising of a 410 coupled to an array of 420 throughout its length is fabricated and tested.

Microstrip is used in the design as it can be easily meandered, hence offering a compact design. An array of 3196 420 is laid out in series along the length of the microstrip top conductor 411.

The change in 413 when coupled to the 420 can be derived analytically. This derivation is inspired by the effective inductance expression for single 420 coupled to the RF tank circuit.

The microstrip TL has inductance per unit length Lₘ 413 and capacitance per unit length Cₘ 424 as indicated in the equivalent circuit in FIG. 4. The inductance of the SQUID loop is L_{sq} 421, coupled to the TL with mutual inductance M 430.

The coupling coefficient, K relates the mutual inductance M (430) and the self-inductances of 420 and microstrip TL 411 as K²=M²/(Lₘ/L_{sq}).

Any 3D electromagnetic simulation code based on finite element modeling can be used to compute 430 and coupling coefficient K. The values of 430 and K increases notably when the gap between 420 and 411 is reduced. At certain point 430 and K stops increasing further, thus a very little change can be observed. The gap is also limited by the microfabrication process.

When the RF power P_{rf} is provided at 426, an equivalent RF current I_{rf} passes through the 425, which can be calculated from the expression: I_{rf}=P_{rf}/Z, where Z is the characteristic impedance of the 411 or 311 in general microstrip TL and optimized to achieve an impedance of 50Ω.

It is required to keep the coupling 430 weak as coupling weakly to a large number of SQUIDs 420 not only provides the desired inductance change but also has an advantage that the RF current in each 420 is smaller than the 425. Hence, the low power handling capabilities of each 420 will limit the maximum operational power of the device at a much larger value as opposed to the case of strong coupling.

Assuming the non-linear effects are negligible, in the present disclosure, the linear mode of operation using a small signal model, and the effective inductance change of the TL is derived.

Due to the RF current, magnetic field is generated around the 425 for a unit cell or 411 for the complete array of 420, which acts as external magnetic flux. If ϕ is the total magnetic flux under the length of microstrip corresponding to one 420, due to flux quantization condition, a circulating current i_{sq} is induced in order to screen the flux.

The flux due to the circulating current also adds to the total flux in the 420 i_{sq}, which is given by: ϕ_{sq}=ϕ+L_{sq}i_{sq}.

The amount of circulating supercurrent i_{sq} is determined by the 422 and given by: i_{sq}=−I_{c} sin φ−ϕ₀(1/Rⱼ) dφ/dt−ϕ₀Cⱼ d²φ/dt², where I_{c} is the critical current of the 422, ϕ₀ is the flux quantum, Rⱼ is the resistance of 422, Cⱼ is the capacitance of 422, and φ is the phase across the 422 given by: φ=2πϕ_{sq}/ϕ₀.

The value of I_{c} is determined by the area of the 422 and the current density J_{c} dictated by the fabrication process.

The flux around the 411 covering a unit 420 if given as: ϕ=Mi_{rf} and the total SQUID flux is given by: ϕ_{sq}=Mi_{rf}+L_{sq}i_{sq}. The 420 can be operative in two different modes: dispersive and dissipative.

This behavior is characterized by the screening parameter of the 420, given by β=2πL_{sq}I_{c}/ϕ₀.

The value of f should be less than 1 to get the 420 operates in dispersive mode, such that the internal flux increases monotonically with the flux ϕ.

The inductance 421 is a combination of the junction inductance and the inductance of the superconducting loop can be obtained by: L_{eff}=−dϕ/di_{sq}.

Differentiating ϕ_{sq}=Mi_{rf}+L_{sq}i_{sq} with respect to i_{sq} and further combining the equations leads to L_{eff}=L_{sq}+Lⱼ, where Lⱼ is the equivalent inductance of 422.

The effective inductance of the microstrip, Lₘ′ coupled to 420 using the equivalent circuit 450 in FIG. 3 is given as: Lₘ′=Lₘ[1−K²(L_{sq}/(LⱼL_{sq}))].

The inductance of the 425 is changed as Lₘ′=Lₘ(1−ΔL) and the relative change in inductance is expressed as ΔL=K²/(1+1/β cos(2πϕ_{sq}/ϕ₀)).

The phase velocity of the signal on 425 initially given by vₚₕ=1/\sqrt{LₘCₘ} will reflect the variable inductance of the 425 and is given by vₚₕ′=1/\sqrt{Lₘ′Cₘ′}. This change in wave velocity and hence the phase delay in the microstrip TL can also be achieved by using only the DC control current or superimposing a DC current on the RF signal current, or by providing external control flux.

The phase, θ of the microstrip line 411 of length lₜₒₜₐₗ coupled with an array of rf-SQUIDs 420 is given by: θ=ω\sqrt{Lₘ′Cₘ}×lₜₒₜₐₗ.

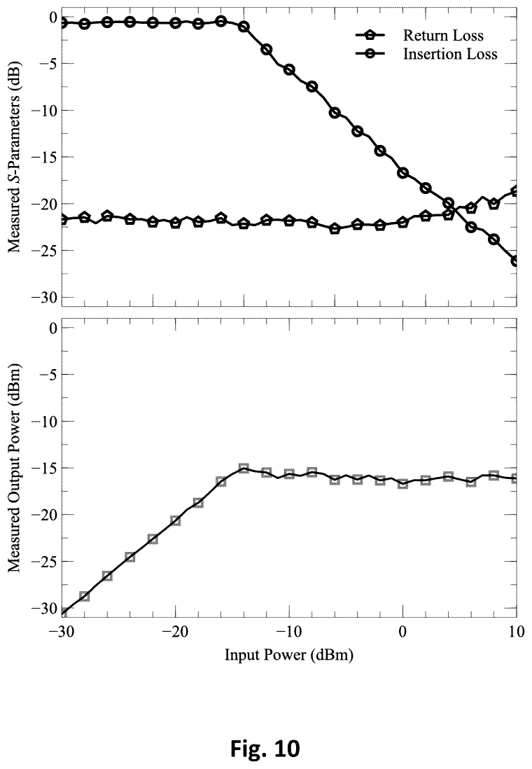

Using the dimensional parameters of the design, the simulated values of the 430 and K from a commercial electromagnetic suite, the expected phase change at 10 GHz with the input RF power ranging from −30 dBm to +10 dBm is shown in FIG. 10.

The phase change of 1760 is observed at 10 GHz between operation range of 9 GHz to 11 GHz when the RF power given at port 401 is swept from −30 dBm to +10 dBm.

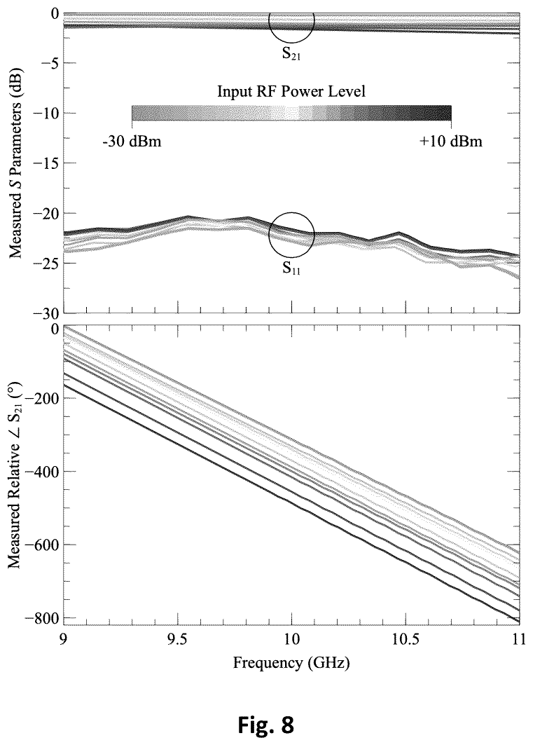

The insertion loss measured at port 402 stays below 1.6 dB for all input power levels, and the return loss is maintained at >20 dB as illustrated in FIG. 8.

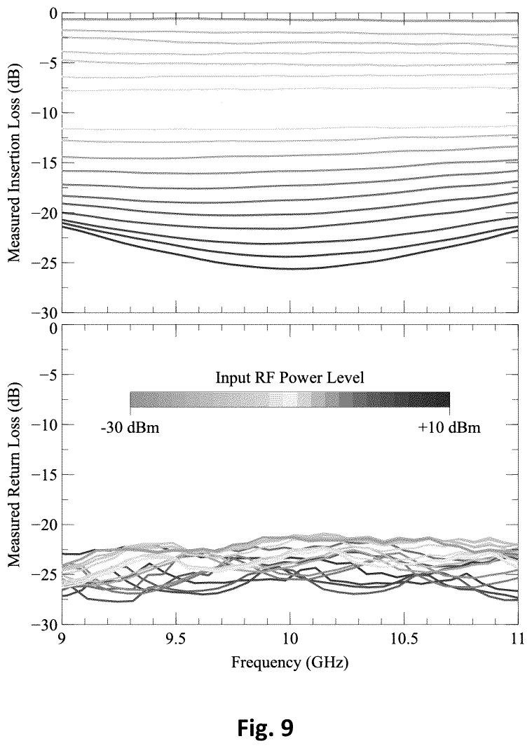

Referring FIG. 9, the fabricated power limiter is measured at different RF power levels ranging from −30 dBm to +10 dBm and the measured insertion loss and return loss over the frequency range 9 GHz to 11 GHz are illustrated.

At the center frequency of 10 GHz, the insertion loss increases from 0.3 dB to 24 dB for the input RF power sweeping from −15 dBm to +10 dBm while no change in the insertion loss is observed up to −15 dBm and the insertion loss curves overlap at 0.3 dB.

The measured return loss at the input port is maintained at better than 20 dB for all power levels. Two tone intermodulation testing is performed at 10 GHz, with a frequency separation of 10 MHz between the two signals.

The power limiter offers minimum attenuation when a low-power signal is incident on it, but as the signal crosses the threshold level, the attenuation starts increasing with increasing power as illustrated in FIG. 10.

The incident RF power is transmitted through the circuit with minimum insertion loss at low power levels until the threshold value of −15 dBm is reached.

When the input RF power increases above the threshold value, the signal is attenuated, and the output signal level is limited at −15 dBm.

Since the power limiting operation has a periodic dependence on the relative phase difference between the two microstrip TLS, the maximum power limiting is obtained at the RF power corresponding to 180° relative phase difference.

As observed from the measurement results in FIG. 8, a phase shift of 176° is obtained at +10 dBm input RF power, hence the power limiting operation can be achieved up to ≈12 dBm, beyond which the output power will linearly start increasing with the input power.

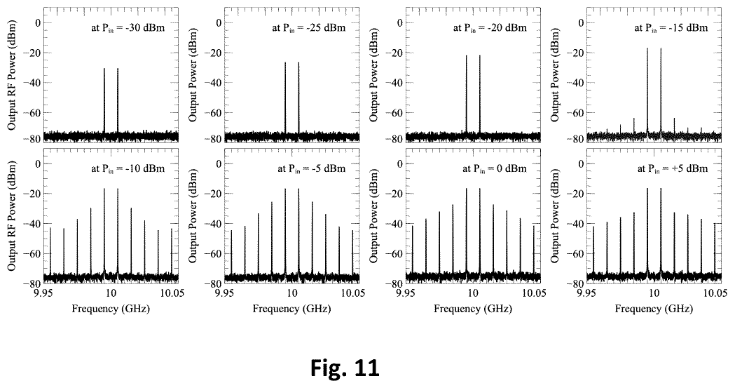

The measurements results shown in FIG. 11 reveal that no nonlinear harmonics are present at the power limiter output spectra at the levels of input signal up to at least −20 dBm. The intermodulation products start appearing in the spectrum at power levels≥−15 dBm but keep a significantly low amplitude.

The phase of the 450 can be controlled using various methods including but not limited to dc current, external magnetic field, RF power, or DC superimposed with RF power.

One embodiment of the present system comprises of two quadrature hybrid couplers and two microstrip transmission line (TL) sections. 1. One of the TL is tightly coupled to an array of rf-SQUIDs and acts as a phase shifter, hence, provides a variable phase θ₂ controlled by dc current. The other microstrip TL offers a fixed phase θ₁. When the input is a function of the phase difference Δθ=θ₂−θ₁ between the two TLs. The signal at the first port is given as ja₁ sin(Δθ/2) while the signal at second port is given by −ja₁ cos(Δθ/2). Hence, in principle, the ratio of input signal divided between the two ports can be adjusted to any level by simply varying the phase shift. For instance, when the phase difference is 0°, the entire input signal is routed to the second port while for a phase difference of 180°, the entire signal is routed to the first port. For all the phase shift values between 0° to 180°, different levels of signal attenuation are attained at second port, while the remaining signal is routed to the first port which is terminated in 50Ω matched load.

Fabrication Process: The resonator is fabricated using MIT Lincoln Laboratory (MIT-LL) SFQ5ee superconducting integrated circuit fabrication process (ref. 1). The process cross section of test embodiment had eight niobium (Nb) layers (M0-M7) and one layer of high kinetic inductance superconducting layer (HKIL) L0. There were three remaining normal metal layers: a mΩ-range resistor layer R4, a high-sheet-resistance (HSR) layer R5, and a Au/Pt/Ti layer M8 used for the RF/dc pads or contact metallization for chip packaging. All metal and resistor layers were interconnected by vias C0, C4, C5, and 10-17. The process offers JJs based on Nb/Al—AlOₓ/Nb tri-layer with current density J_{c} of 10 kA/cm². The JJs are formed between layers M5 and J5, while the wiring connections for J5 are made on M5 connected using via C5.

Hybrid Coupler Quadrature hybrid coupler having four-port device with Port 1, Port 2, Port 3 and Port 4 acting as input, through, coupled and isolated ports, respectively. A tandem configuration is used in the proposed design, comprising two parallel coupled lines placed side-by-side. The length of each coupled line section is designed to be quarter wavelength (λ/4) at 10 GHz, and is further optimized to achieve the desired 3 dB coupling performance using simulations in Sonnet EM. The design requires very tight gap (≤1 μm) between the two tandem signal lines and crossover interconnects between the two signal lines and the ground planes. The design is realized using MIT-LL multi-layer fabrication process, which provides three primary design advantages: (i) allows small feature size gap between the Nb coupled lines, (ii) the interconnects can be routed from a second Nb layer using vias, and (iii) the Nb based implementation allows monolithic integration with other superconducting components in complex circuits. The fabricated standalone hybrid coupler is tested in a Lakeshore cryogenic probe station at 4 K with Keysight PNA-X. The two-port S-parameter measurement is performed by terminating two of the four ports of the hybrid coupler with monolithically integrated 50Ω micro-resistors (ref. 2) The measurement results agree well with the simulated performance and excellent 3 dB coupling is observed over a wide frequency range 8 GHz to 18 GHz with the less that 1 dB measured insertion loss at the coupled port less and better than 22 dB return loss at the input port.

Phase Shifter: The phase shifter is realized using a microstrip transmission line coupled to an array of rf-SQUIDs. Each rf-SQUID consists of a superconducting loop shunted by a Josephson junction (JJ). Its behavior combines the physical phenomenon of flux quantization in a superconducting loop and the Josephson tunneling effect (ref. 3).

The rf-SQUIDs are highly sensitive to magnetic flux and show a change in inductance with changing external magnetic flux. In other words, rf-SQUID acts as variable inductor when the magnetic flux coupled to the superconducting loop changes. This can be used to an advantage by placing an array of rf-SQUIDs in close proximity (stronger coupling) to a superconducting microstrip transmission line. The coupling coefficient, K gives a relation between the self-inductances of rf-SQUID (Ls) and microstrip TL unit cell (L) and the mutual inductance (M) between the two.

$${K}^{2} = \frac{{M}^{2}}{{LL}_{s}}$$

The rf-SQUID can operate in either dispersive or dissipative mode depending on the screening parameter

$$β = \frac{2 π {L}_{s} {I}_{c}}{{φ}_{0}}$$

where, I_{c} is the critical current of the JJ and φ₀=2.0679×10⁻¹⁵ Wb is the magnetic flux quantum.

In this design, the value of screening parameter β is 0.6, hence the SQUID operates in dispersive mode. The physical realization of the circuit was shown an array of 230 rf-SQUIDs placed along the meandered microstrip TL. The overall footprint of the phase shifter is 0.64 mm×0.55 mm. Alternatively, the SQUIDs can be placed between the top conductor of the microstrip and the ground plane using two additional Nb layers (ref. 4). The microstrip top conductor is designed on the Nb layer M6 while the ground plane is on layer M1 maintaining the characteristic impedance at 50Ω. The SQUID loops are designed on layer M6 at a gap of 1 μm from the microstrip TL and the Nb—AlOₓ—Nb JJ shunting the loop is formed between layers M6 and M5 in the fabrication process. A variable dc current is provided to a second microstrip line on layer M6 running parallel to rf-SQUIDs. This current creates a magnetic flux which couples to the rf-SQUID.

Hence, the rf-SQUID loop lies between the rf microstrip line and the dc control line. The dc control current could also be potentially applied through bias tees directly on the RF input port (ref. 4, 5). In that case, the control current cannot be exceeded beyond the threshold critical current of the superconductor, or the material will switch to its non-superconducting state and the device performance suffers significantly. With the change in dc current, the flux coupled to the rf-SQUIDs changes, which in effect changes its inductance. This causes a change in inductance of the microstrip transmission line due to the mutual coupling to the array of rf-SQUIDs. The analytical expression for the effective inductance of the microstrip TL unit cell when coupled to a rf-SQUID is given as (ref. 6).

L=L(1−ΔL)

where ΔL is given by:

$$Δ L = \frac{{K}^{2}}{1 + 1 / βcos ( 2 {πφ}_{s} / {φ}_{0} )}$$

This change in inductance of the microstrip transmission line reflects as a change in phase of the output RF signal. Testing the fabricated device at 4 K, a phase shift of 130° is measured at 10 GHz and 184° at 15 GHz with dc current varying from 0 mA to 4.5 mA while the input RF power is maintained at −20 dBm. For the entire frequency range from 1 GHz to 20 GHz, the insertion loss (|S₂₁|) is less than 2 dB and the return loss (|S₁₁|) is better than 18 dB. The phase shift can also be achieved by varying the input RF power. The device demonstrates excellent phase shifting response from −30 dBm to +10 dBm, beyond which the intermodulation products limit the maximum phase shift.

To verify the concept and study any coupling effects between the microstrip RF line and the dc control current microstrip line, another design identical to the prior design was fabricated but without the rf-SQUIDs. The measurement results show no phase shift with the dc current sweep. This proves that the phase shift is due to the variable inductance from the rf-SQUIDs.

The variable attenuator design, consists of a hybrid coupler 1 which splits the input RF signal equally between two microstrip lines, one of which is coupled to 230 rf-SQUIDs placed along its length. The other end of the microstrip lines are connected to hybrid coupler 2 which combines the signals and provides the attenuated signal at the RF output port. The unused ports of the hybrid couplers are terminated in matched load using 50Ω monolithically integrated microresistors using the high-sheet-resistance layer R5 in the fabrication process. The second callout in the image shows the interconnections in the hybrid coupler design routed from a second Nb layer using vias. The gap g₁=1 μm, gap g₂=2 μm, I_{c}=8 μm and wₛ=20 μm. The rf-SQUID design is highlighted in the third callout where g_{sq}=1 μm, w_{sq}=18 μm and l_{sq}=17 μm. The 0JJ used in the design is 3 μm, which is a tri-layer junction as shown in the rendered image in the fourth callout of FIG. 10. The overall device dimensions are 2.6 mm×0.5 mm. The two microstrip lines are arranged on different Nb layers (M6 and M1) with a common ground plane between them (M4). The rf-SQUIDs are placed along the top microstrip.

The device is tested in a Lakeshore cryogenic probe station in which the fabricated chips are loaded on a 4 K stage. The chamber has two RF probes connected to the Keysight PNA-X and two DC probes connected to a source measure unit (SMU) to provide precisely controlled dc current. The probe station is cooled down to 77 K using liquid nitrogen, followed by liquid helium to further cool it down to 4 K. The S-parameters of the variable attenuator are measured as a function of the applied control current to the dc control line while maintaining the input RF power level at −20 dBm. With no dc current flowing in the control line, the device shows minimum insertion loss (|S₂₁|) in the X-band and Ku-band. For a control current sweep from 0 mA to 4.5 mA, a flat analog precisely controlled attenuation increasing up to 35 dB is measured in the X-band. In the Ku-band, a larger attenuation range is observed (as expected from higher phase shift). The observed return loss (|S₁₁|) is better than 17 dB in both X- and Ku-band.

In summary, the present invention experimentally demonstrated a LTS analog microwave variable attenuator which can be monolithically integrated with other components on the superconducting chip. The variable attenuator design uses two wideband hybrid couplers and a phase shifter. The phase shifter realized using a superconducting microstrip transmission line coupled to an array of rf-SQUIDs provides a phase shift of 130° at 10 GHz and 184° at 15 GHz. The variable phase shift is controlled by using dc current, which effectively controls the level of attenuation at the output. The variable attenuator exhibits more than 30 dB of precise analog flat attenuation tuning range in the X-band with more than 45 dB of dc current controlled attenuation in Ku-band. The device is fabricated using a multilayer advanced superconducting process by MIT Lincoln laboratory. The large variable attenuation range demonstrated by the device and its potential for monolithic integration with other Nb-based circuits makes it a desirable candidate for quantum circuit measurements.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

With respect to the above description, it is to be realized that the optimum relationships for the parts of the invention in regard to size, shape, form, materials, function and manner of operation, assembly and use are deemed readily apparent and obvious to those skilled in the art, and all equivalent relationships to those illustrated in the drawings and described in the specification are intended to be encompassed by the present invention.

### REFERENCES

(1) S. K. Tolpygo, V. Bolkhovsky, T. J. Weir, A. Wynn et al., “Advanced fabrication processes for superconducting very large-scale integrated circuits,” IEEE Trans. Appl. Supercond., vol. 26, no. 3, pp. 1-10, April 2016.
(2) N. K. Khaira, T. Singh, and R. R. Mansour, “Cryogenic wideband quadrature hybrid couplers implemented in a low temperature superconductor multilayer process,” in Proc. IEEE MTT-S Intl. Microw. Symp. (IMS), Denver, CO, USA, June 2022, pp. 160-163.
(3) J. Clarke and A. I. Braginski, The SQUID Handbook: Fundamentals and Technology of SQUIDs and SQUID Systems. Wiley Online Library, May 2004, vol. 1.
(4) N. K. Khaira, T. Singh, and R. R. Mansour, “Josephson junctions-based low-temperature superconducting phase shifter for X-and K-Bands using MIT-LL SFQ5ee process,” IEEE Microw. Wireless Compon. Lett., vol. 32, no. 6, pp. 1-4, June 2022, doi:10.1109/LMWC.2022.3163351.
(5) C. M. Jackson, J. H. Kobayashi, E. B. Guillory, C. Pettiette-Hall et al., “Monolithic HTS microwave phase shifter and other devices,” J. Supercond., vol. 5, no. 4, pp. 417-422, 1992.
(6) A. Barone and G. Paterno, Physics and applications of the Josephson effect. Wiley Online Library, 1982, vol. 1.

What is claimed is:

1) A power dependent power limiter, the power limiter comprising:
a) an input quadrature hybrid coupler having a first input port, a first thru port, a first coupled port, and a first isolated port;
b) an output quadrature hybrid coupler having a second input port, a second thru port, a second coupled port, and a second isolated port;
c) a fixed phase transmission line having a first transmission input port that is in communication with the first output port of the first quadrature hybrid coupler and having a first transmission output port that is in communication with the second input port of the output quadrature hybrid coupler;
d) a tunable phase transmission line having a second transmission input port that is in communication with the first coupled port of the first quadrature hybrid coupler and having a second transmission output port that is in communication with the second isolated port of the output quadrature hybrid coupler;
e) wherein the fixed and tunable phase transmission lines are superconducting microstrip transmission lines;
f) wherein the input and the output quadrature hybrid couplers have co-planar waveguide (CPW) based tandem coupled line architecture to allow for a monolithic integration with other superconducting devices, and
g) wherein the first and the second isolated ports are terminated with a first and a second matched loads, respectively, and wherein the first and the second matched loads are exactly the same,
whereby an RF power provided to the fixed and tunable phase transmission lines controls a flux through rf-SQUIDs, wherein each rf-SQUID acts as a flux sensitive variable inductor, and since it is magnetically coupled, change in rf-SQUID inductance causes change in the effective inductance of the tunable phase transmission line and hence a phase of an output signal, and whereby the power limiter acts as a variable attenuator to reduce the signal power level.

2) The power limiter of claim 1, wherein the fixed and tunable phase transmission lines comprising a top conductor and a bottom or ground conductor having inductance and capacitance, wherein an RF signal travels between input and output ports.

3) The power limiter device of claim 1, wherein the fixed and tunable phase transmission lines comprising a top conductor and a bottom or ground conductor coupled to an array of radio-frequency superconducting quantum interference devices (rf-SQUIDs) having a Josephson Junction (JJ) and an inductance of the array of rf-SQUID devices, wherein the RF signal travels between input port and output port that are coupled and having a mutual coupling between the fixed and tunable phase transmission lines, whereby the rf-SQUID acts as a tuning element to provide variable inductance coupled with the transmission line.

4) The power limiter device of claim 1, wherein the input and output quadrature hybrid couplers each have a center conductor placed side by side and a set of bridges connecting the individual ground places and the signal lines are routed from a niobium layer using interconnects.

5) The power limiter device of claim 1, wherein each is a Nb-based superconducting loop extending on two niobium layers shunted by the connecting niobium-filled interconnects on one end and a Nb-AlOx-Nb tunnel JJ on the other end.

6) The power limiter device of claim 1, wherein the fixed and tunable phase transmission lines are meandered with a shared ground in order to make the overall device compact in size.

7) The power limiter device of claim 1, wherein the fixed and tunable phase transmission lines are co-planar waveguide (CPW) or strip-line (SL) transmission lines.

8) The power limiter device of claim 1, wherein the rf-SQUIDs are placed directly below, on the side, or embedded across the fixed and tunable phase transmission lines to achieve variable inductance.

9) The power limiter device of claim 1, wherein an active or a passive superconducting element are used to attain either variable inductance, capacitance, or both to achieve a phase difference between two TLs.

10) The power limiter device of claim 1, wherein the HCs have tandem coupled line implementation, or Lange, branch line or similar implementations.

11) The power limiter device of claim 1, wherein HC-a and HC-b are meandered to make the overall device compact in size.

12) The power limiter device of claim 1, wherein an operating frequency of the power limiter is 10 GHz with 2 GHz bandwidth.
